(19) United States
(12) Patent Application Publication
(10) Pub. No.: US 2025/0107106 A1
(43) Pub. Date: Mar. 27, 2025

(54) MEMORY DEVICE

(71) Applicant: MACRONIX International Co., Ltd., Hsinchu (TW)

(72) Inventor: Jung-Chuan Ting, Hsinchu County (TW)

(73) Assignee: MACRONIX International Co., Ltd., Hsinchu (TW)

(21) Appl. No.: 18/471,295

(22) Filed: Sep. 21, 2023

(51) Int. Cl. H10B 80/00; H01L 23/00; H01L 25/00; H01L 25/18

(52) U.S. Cl. CPC H10B 80/00; H01L 24/05; H01L 24/06; H01L 24/08; H01L 25/18; H01L 25/50; H01L 2224/05554; H01L 2224/05647; H01L 2224/06131; H01L 2224/06132; H01L 2224/06133; H01L 2224/06177; H01L 2224/08145; H01L 2224/80357; H01L 2224/80379; H01L 2224/80896; H01L 2924/0504; H01L 2924/0544

(57) ABSTRACT

A memory device includes a substrate, a bonding structure and bit lines. The substrate includes adjacent first and second regions. The bonding structure is over the substrate and includes a bonding dielectric layer and first and second bonding pads. The bonding dielectric layer is over the substrate in the first and the second regions. The first and second bonding pads are respectively embedded in the bonding dielectric layer over the substrate in the first and second regions. The bit lines are over the bonding structure and extend from the first region to the second region. A density of the first bonding pads in the first region is greater than a density of the second bonding pads in the second region. The memory device may be 3D NAND flash memory with high capacity and high performance.

### BACKGROUND

### Technical Field

The embodiments of the present disclosure relate to a semiconductor device, and particularly to a memory device.

### Description of Related Art

A non-volatile memory device (e.g., a flash memory) has the advantage that stored data does not disappear at power-off, so it becomes a widely used memory device for a personal computer or other electronic equipment.

Currently, the flash memory arrays commonly used in the industry include a NOR flash memory and a NAND flash memory. The NAND flash memory has multiple memory units connected in series, so the NAND flash memory has better integration and area utilization than the NOR flash memory, and has been widely used in various electronic products. In addition, in order to further enhance the integration of memory devices, a 3-dimensional NAND flash memory has been developed. However, there are still many challenges associated with a 3-dimensional NAND flash memory. For example, the bit line may not be able to connect to the via, causing reliability issues.

### SUMMARY

A memory device according to an embodiment of the present disclosure includes a substrate, a bonding structure and a plurality of bit lines (BL). The substrate includes a first region and a second region adjacent to each other. The bonding structure is disposed over the substrate and includes a bonding dielectric layer, a plurality of first bonding pads and a plurality of second bonding pads. The bonding dielectric layer is disposed over the substrate in the first region and the second region. The first bonding pads are embedded in the bonding dielectric layer over the substrate in the first region. The second bonding pads are embedded in the bonding dielectric layer over the substrate in the second region. The bit lines are disposed over the bonding structure, the bit lines extend from the first region to the second region, and each of the first bonding pads is electrically connected to one of the bit lines. A density of the first bonding pads in the first region is greater than a density of the second bonding pads in the second region.

Based on the above, in the memory device of the embodiments of the present disclosure, by increasing the density of the bonding pads in the memory array region, the number of the contacts connected to the bit line may be increased, and the electrical connection between the bit line and the contact may be thus ensured. Accordingly, the reliability of the memory device may be improved.

### BRIEF DESCRIPTION OF THE DRAWINGS

FIG. 1A to FIG. 1H are schematic cross-sectional views of a method of fabricating a memory device with a complementary metal oxide semiconductor device (CMOS) bonded to a memory array (CMOS-Bonded-Array, CbA) structure according to an embodiment of the present disclosure.

FIG. 2A to FIG. 2H are other schematic cross-sectional views of a method of fabricating a memory device with a CbA structure according to an embodiment of the present disclosure.

FIG. 3 is a top view of a partial area of a first chip in FIG. 1A.

FIG. 4A is a top view of a partial area of a second chip in FIG. 1C and FIG. 2C.

FIG. 4B is a top view of a partial area of a second chip in FIG. 1D and FIG. 2D.

FIG. 5A to FIG. 5C are top views and a perspective view of a plurality of bonding pads and a plurality of bit lines in two adjacent regions.

FIG. 6A and FIG. 6B are a top view and a perspective view of a plurality of bonding pads and a plurality of bit lines of the same group in the same region.

FIG. 7A and FIG. 7B are a top view and a perspective view of a plurality of bonding pads and a plurality of bit lines of different groups in the same region.

### DESCRIPTION OF THE EMBODIMENTS

A CMOS-Bonded-Array (CbA) structure is a memory device architecture in which a chip having a complementary metal oxide semiconductor device and a memory array chip are boned. In this architecture, a bit line is connected to a page buffer in the CMOS chip through a via, a bonding pad and an interconnect. Multiple vias may be used to connect the bit line and the via, so as to ensure the reliability of the memory device. However, the number of the bonding pads will also increase and the increased number of the bonding pads will occupy more chip area. In the embodiments of the disclosure, by changing the density and the arrangement of the bonding pads, the number of the vias connected to the bit line may be increased without increasing the occupied area, so as to improve the reliability of the memory device.

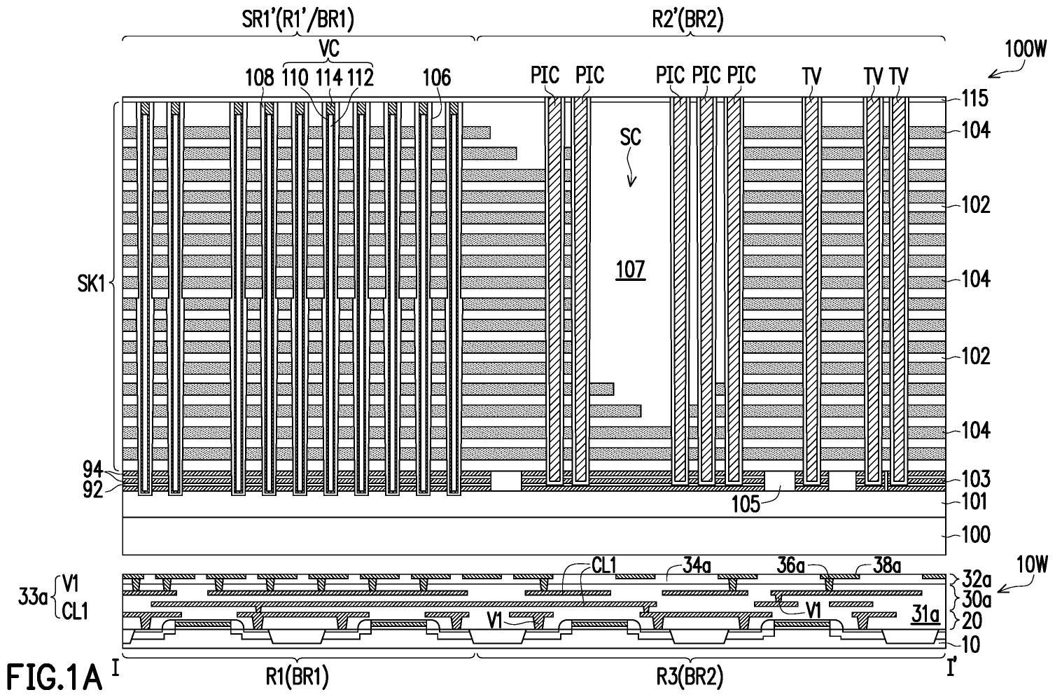

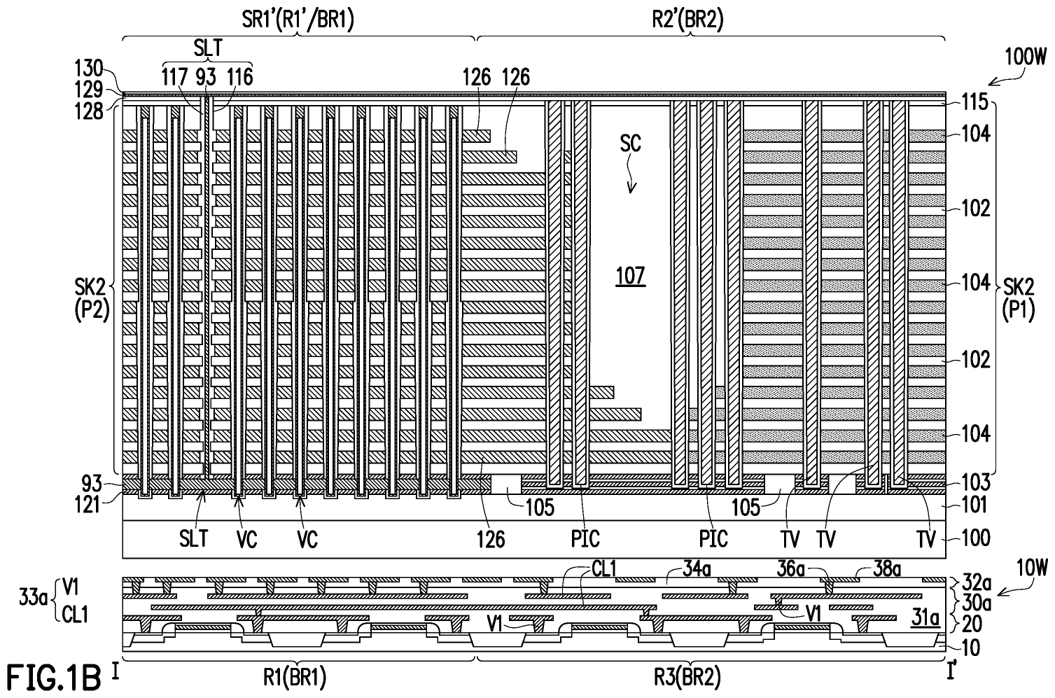

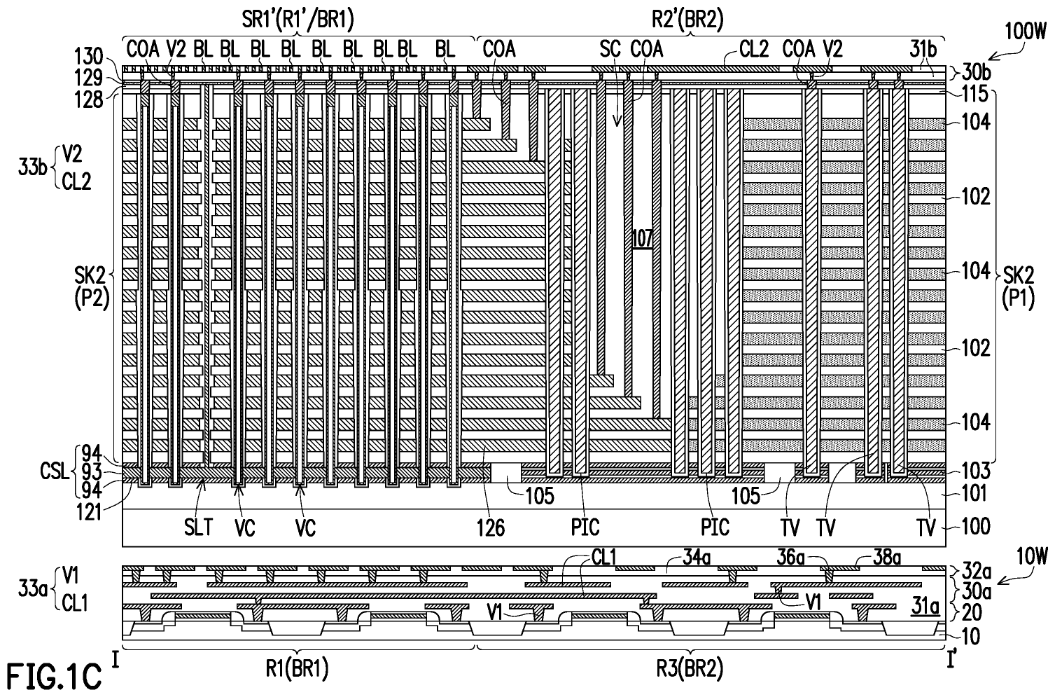

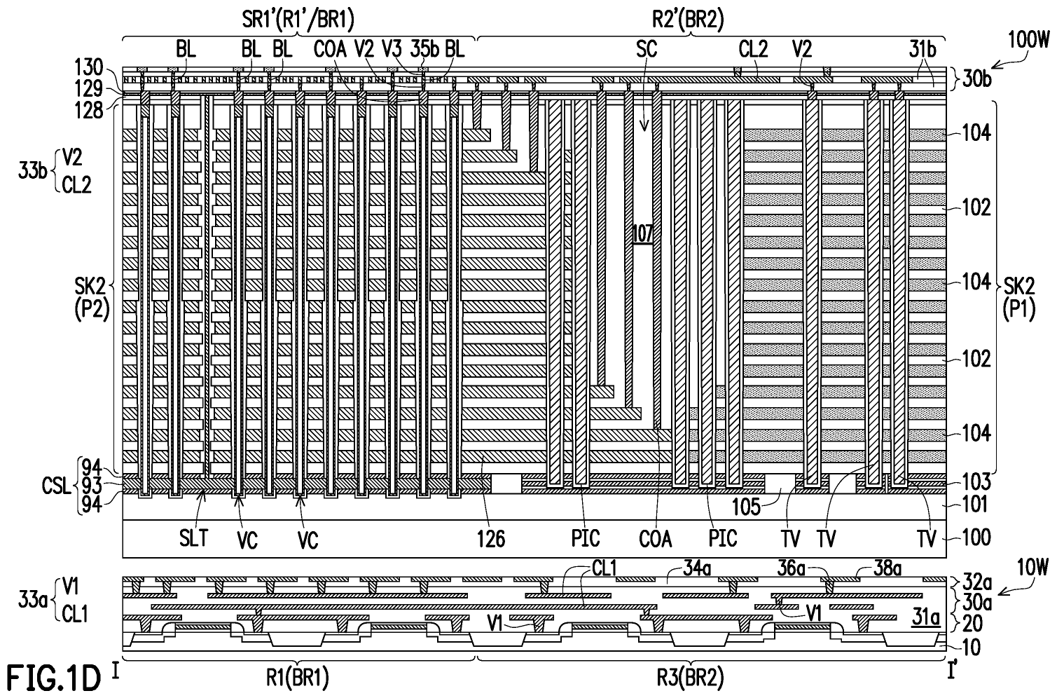

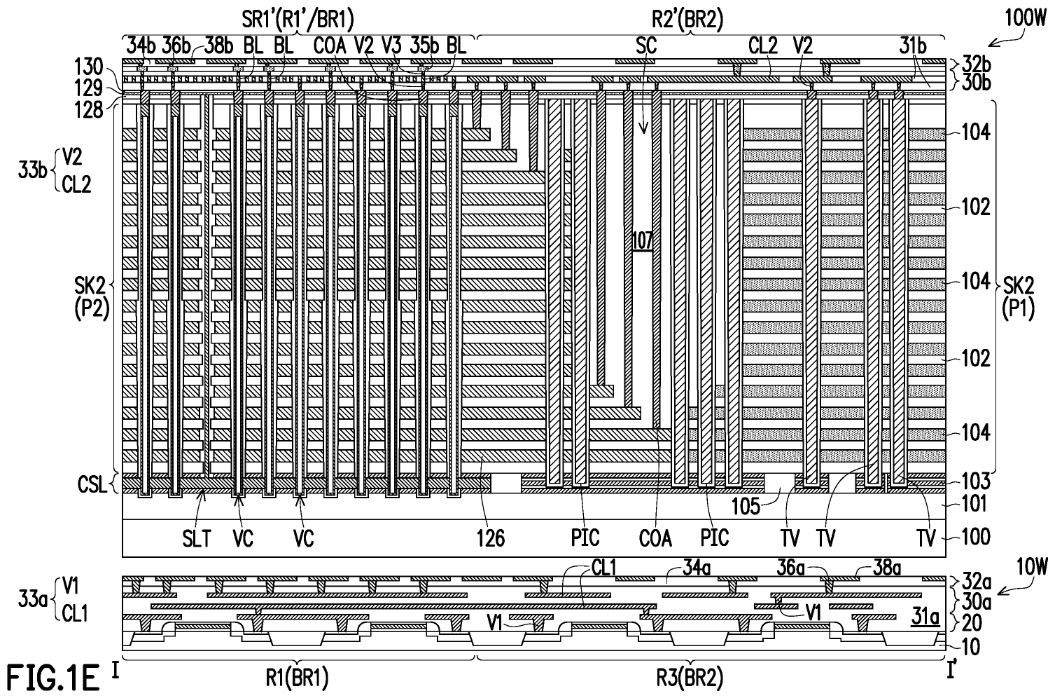

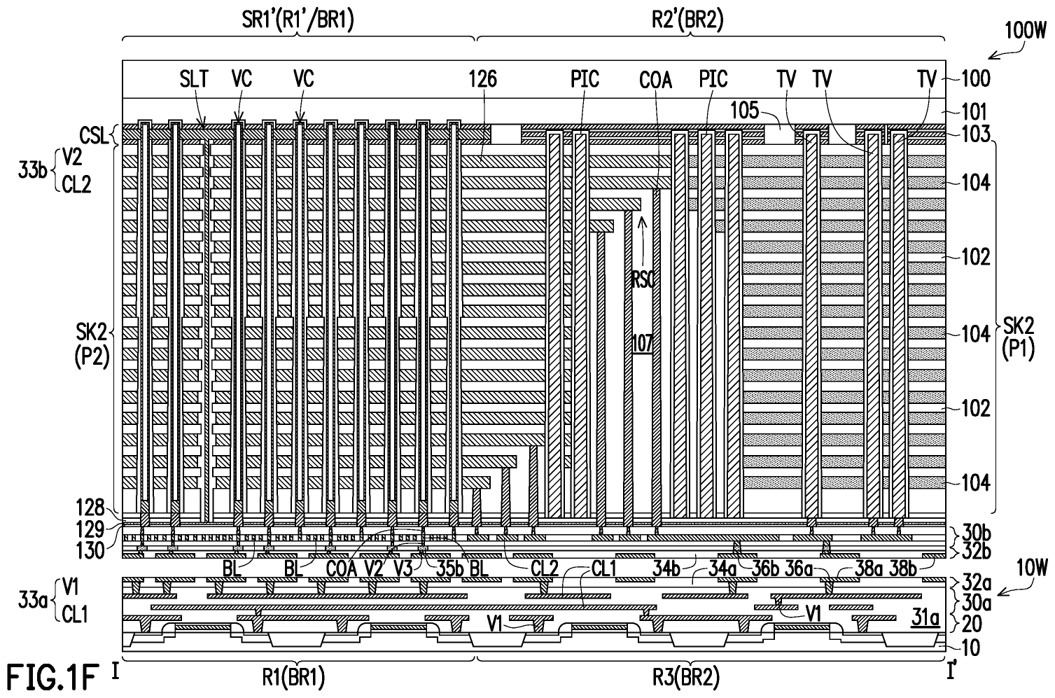

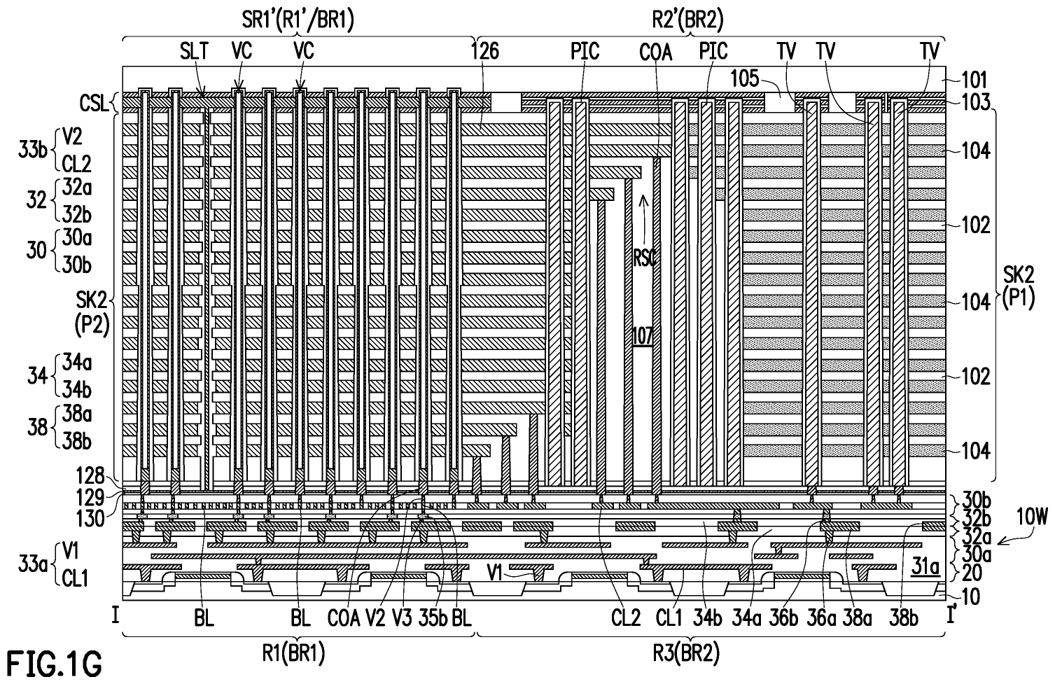

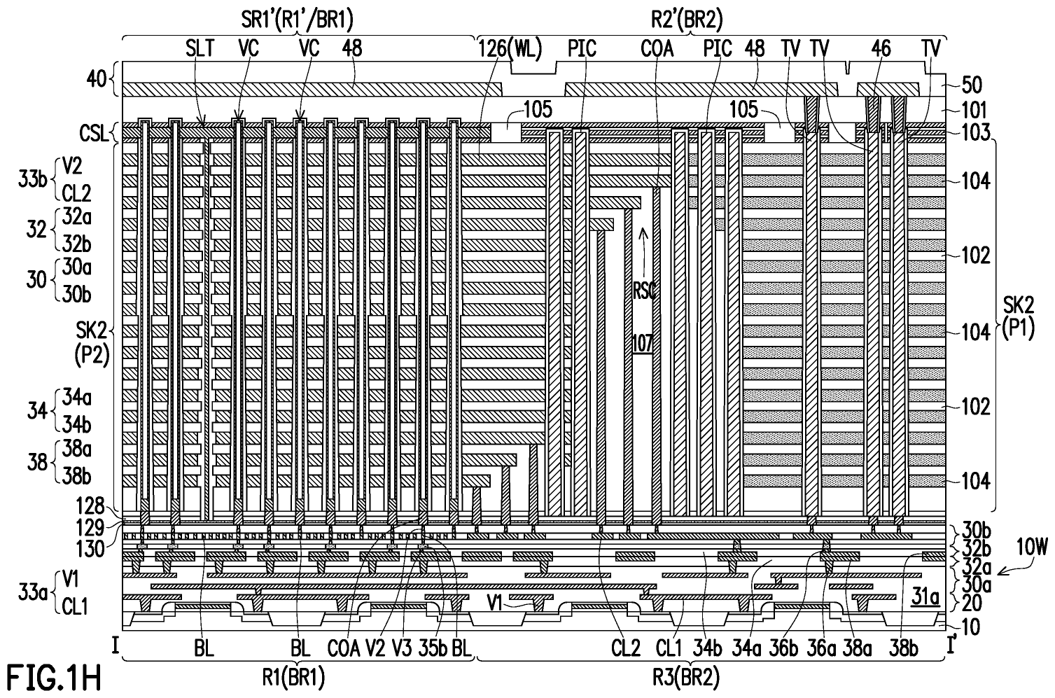

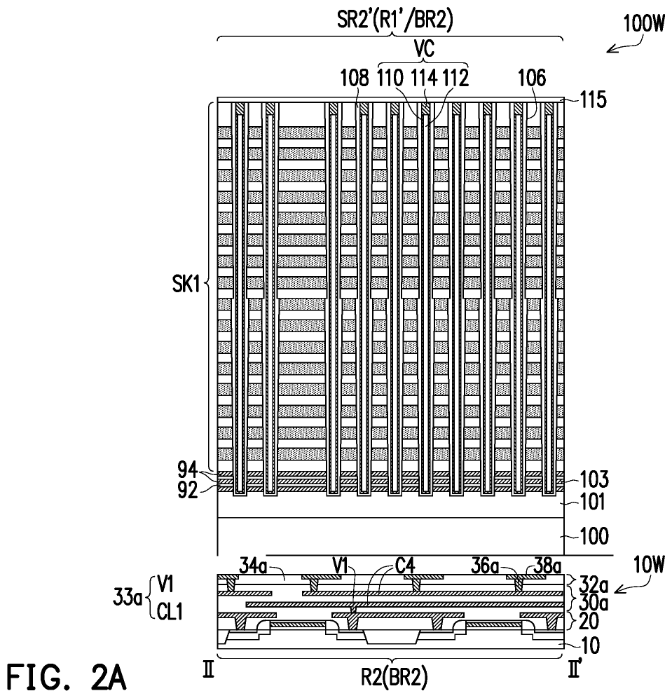

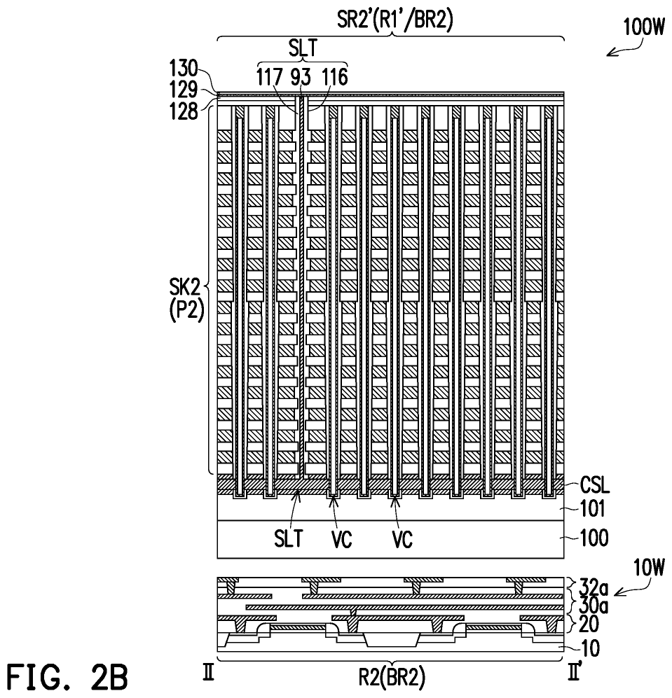

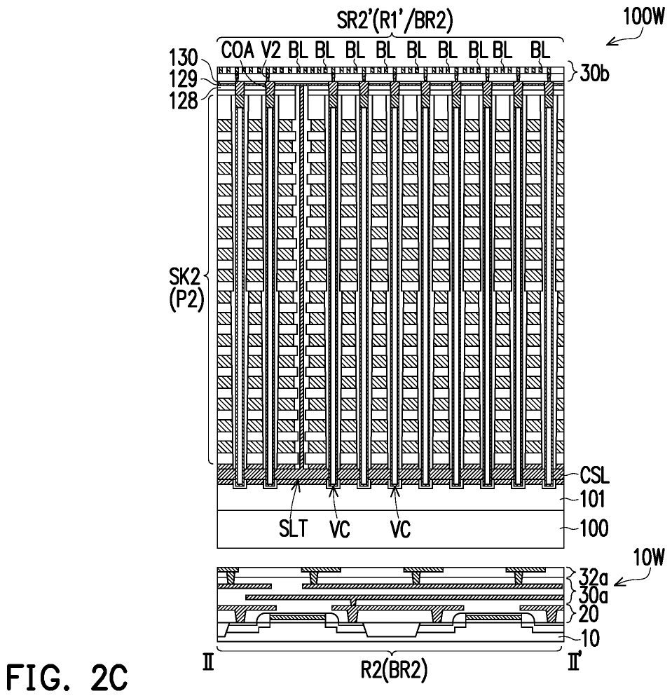

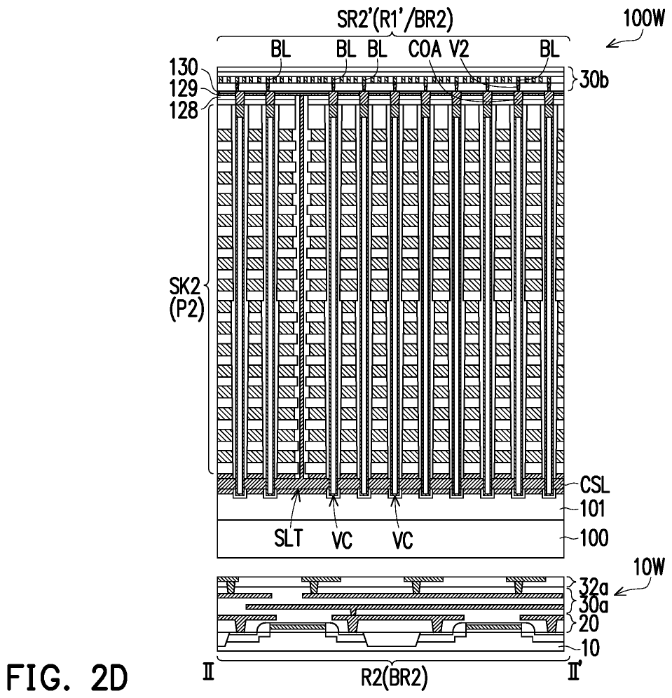

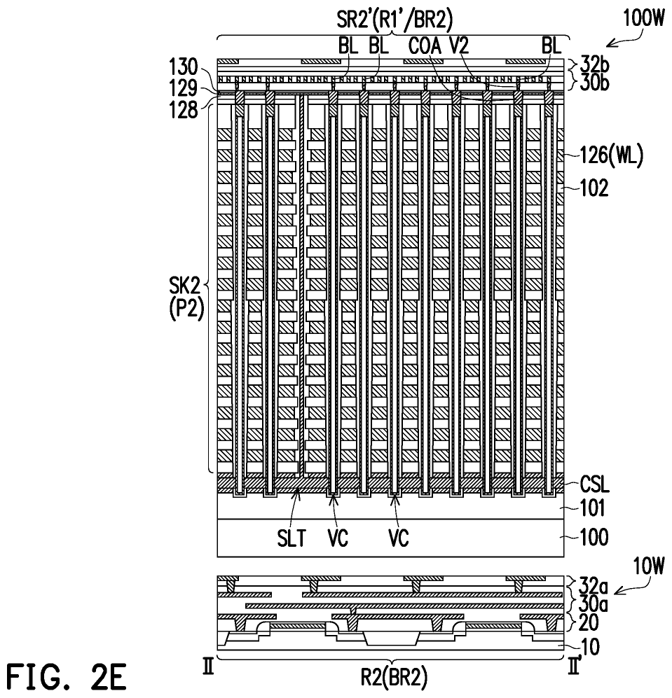

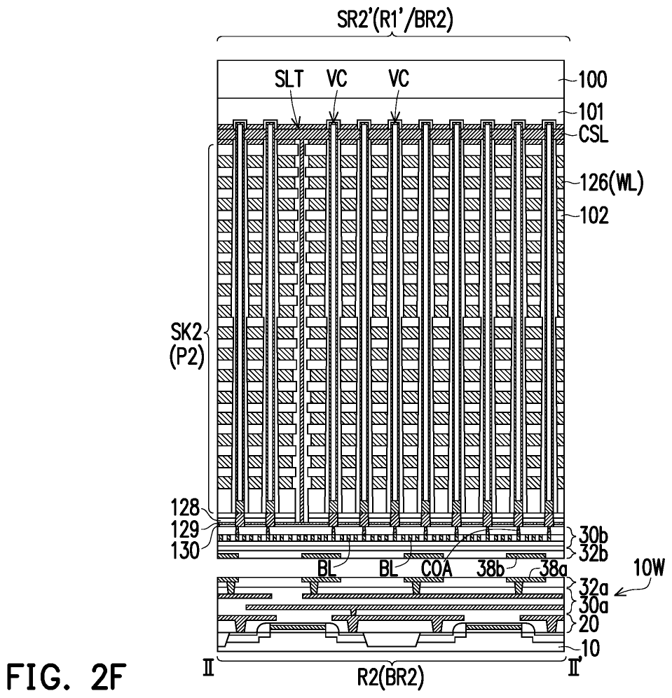

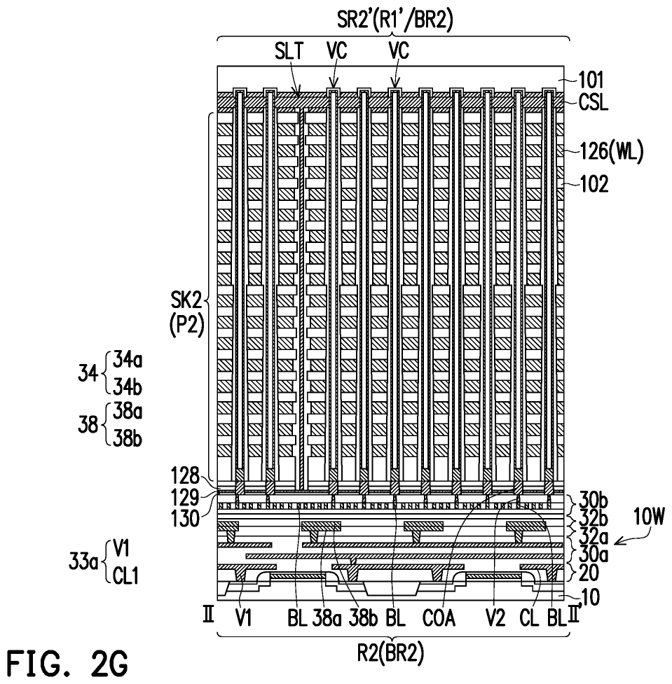

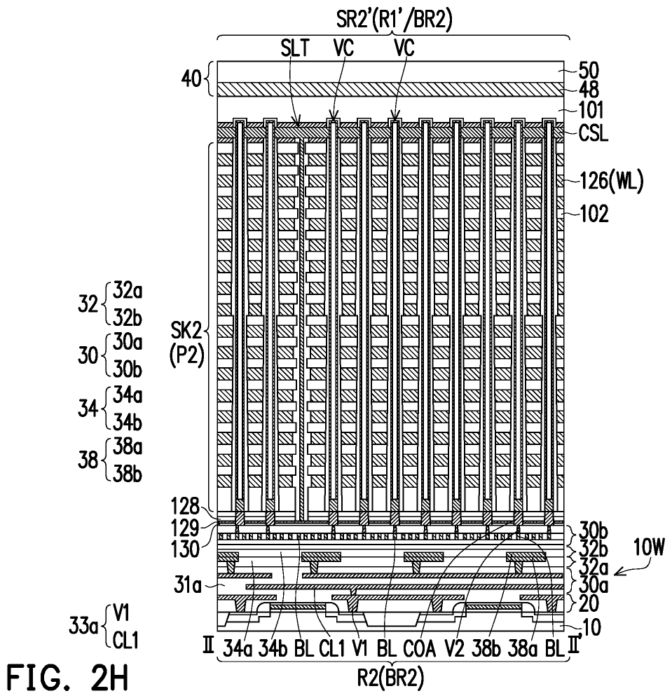

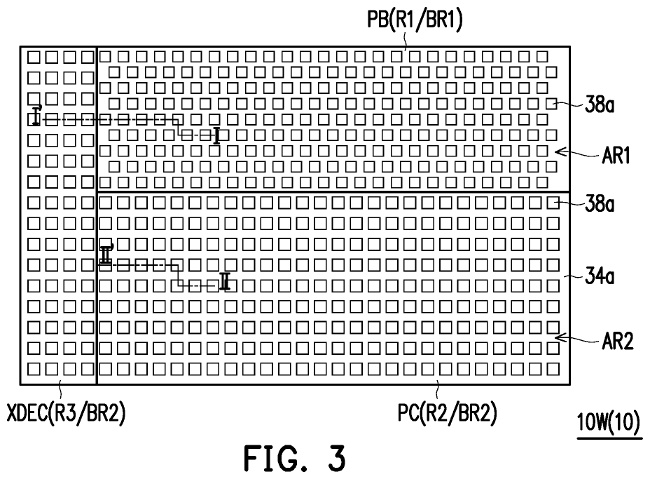

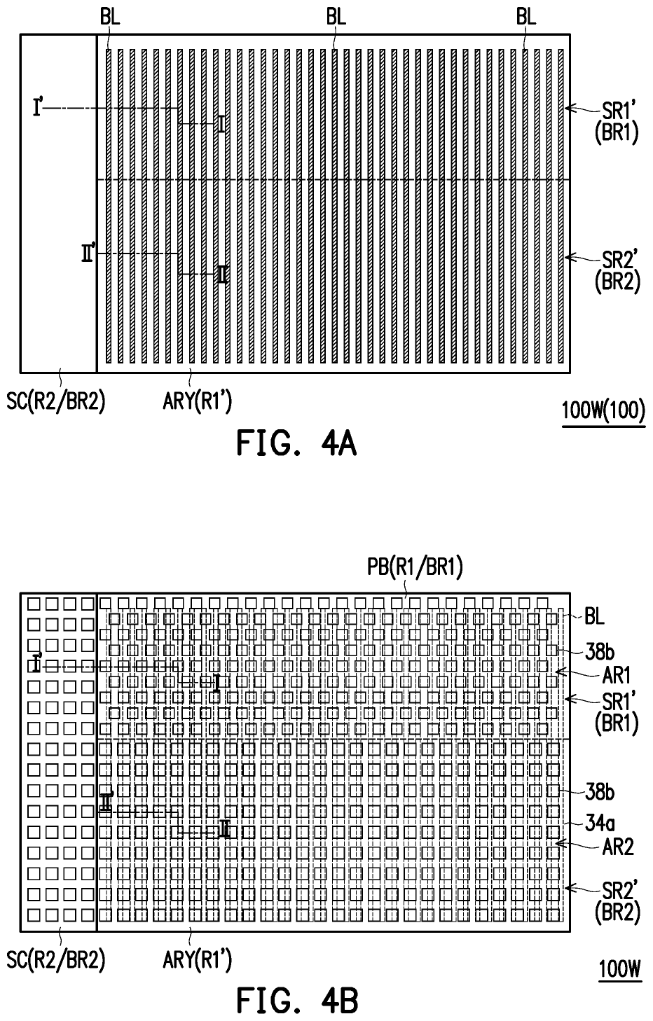

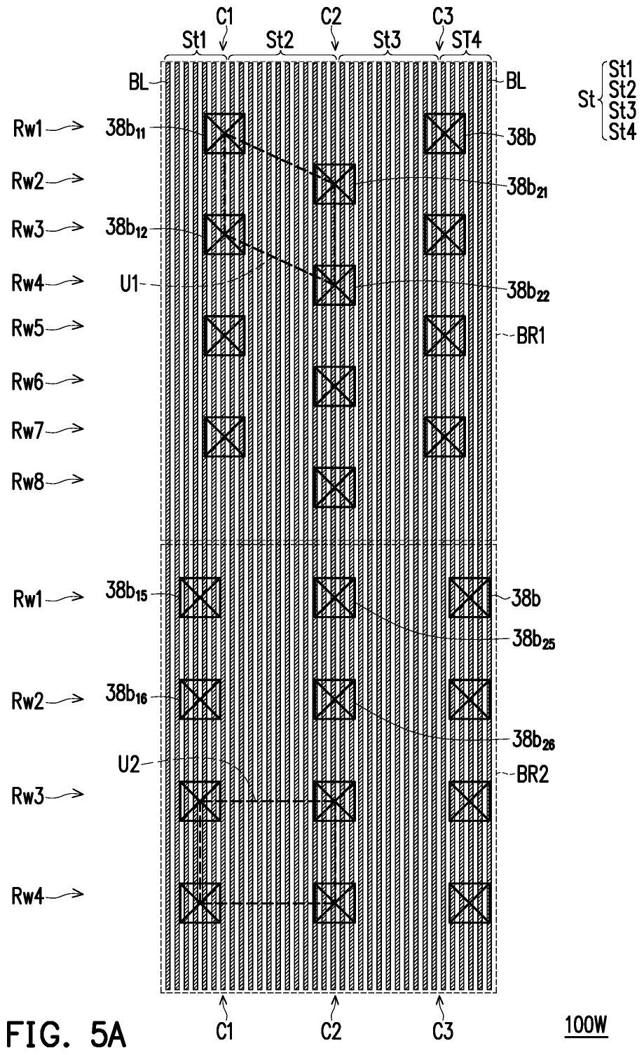

FIG. 1A to FIG. 1H are schematic cross-sectional views of a method of fabricating a memory device with a CbA structure according to an embodiment of the present disclosure. FIG. 2A to FIG. 2H are other schematic cross-sectional views of a method of fabricating a memory device with a CbA structure according to an embodiment of the present disclosure. FIG. 3 is a top view of a partial area of a first chip in FIG. 1A. FIG. 4A is a top view of a partial area of a second chip in FIG. 1C and FIG. 2C. FIG. 4B is a top view of a partial area of a second chip in FIG. 1D and FIG. 2D. FIG. 1A to FIG. 1H are schematic cross-sectional views along line I-I′ of FIG. 3, FIG. 4A and FIG. 4B. FIG. 1A to FIG. 1H are schematic cross-sectional views along line II-II′ of FIG. 3, FIG. 4A and FIG. 4B.

Referring to FIG. 1A, FIG. 2A and FIG. 3, a first chip 10W is provided. The first chip 10W includes a substrate 10. The substrate 10 may be a semiconductor substrate, such as a silicon-containing substrate. The substrate 10 may include regions R1, R2, R3 (shown in FIG. 3). The regions R1, R2 and R3 may also be called a page buffer region, a peripheral circuit region and a row and column decoder region respectively.

Referring to FIG. 1A, FIG. 2A and FIG. 3, a device layer 20 (shown in FIG. 1A) is formed on the substrate 10 in the regions R1, R2, and R3 (shown in FIG. 3). The device layer 20 may include active elements or passive elements. The active elements may include transistors, diodes, or the like. The passive elements may include capacitors, inductors, or the like. The transistors may include an N-type metal oxide semiconductor (NMOS) transistor, a P-type metal oxide semiconductor (PMOS) transistor or a complementary metal oxide semiconductor device (CMOS). The device layer 20 is disposed under a memory array (e.g., disposed under the stack structure SK2 in FIG. 1H or FIG. 2H), and the device layer 20 is, for example, a complementary metal-oxide-semiconductor (CMOS), and thus, this architecture may also be called a complementary metal oxide semiconductor device (CMOS) bonded to a memory array (CMOS-Bonded-Array, CbA) structure. The device layer 20 on the region R1 may include multiple page buffers PB. The device layer 20 on the region R2 may include multiple peripheral circuits PC. The device layer 20 on the region R3 may include multiple row and column decoders XDEC.

Referring to FIG. 1A and FIG. 2A, a first portion 30a of an interconnect structure 30 is formed on the device layer 20. The first portion 30a of the interconnect structure 30 may include multiple dielectric layers 31a and interconnect layers 33a formed in the multiple dielectric layers 31a. The interconnect layers 33a include multiple plugs V1, multiple conductive lines CL or the like.

Referring to FIG. 1A, FIG. 2A and FIG. 3, a first portion 32a of a bonding structure 32 (shown in FIG. 1G) is formed on the first portion 30a of the interconnect structure 30. The first portion 32a of the bonding structure 32 includes a bonding dielectric layer 34a and a bonding plug 36a and a bonding pad 38a embedded in the bonding dielectric layer 34a. The bonding dielectric layer 34a may include silicon oxide, silicon nitride or a combination thereof. The bonding plug 36a and the bonding pad 38a may include copper, for example. The bonding pad 38a is connected to the topmost conductive column CL of the first portion 30a of the interconnect structure 30 through the bonding plug 36a. The bonding pad 38a and the bonding plug 36a may be formed by a single damascene or a dual damascene process. The bonding pad 38a, the bonding plug 36a, and the bonding dielectric layer 34a may be planarized through a chemical mechanical polishing process to be coplanar.

Referring to FIG. 3, in the embodiments of the disclosure, an arrangement of the bonding pads 38a in the region R1 is different from an arrangement of the bonding pads 38a in the regions R2 and R3, so that the density of the bonding pads 38a in the region R1 is greater than the density of the bonding pad 38a in the regions R2 and R3, which will be then described in detail.

Referring to FIG. 1A, FIG. 2A and FIG. 4A, a second chip 100W is provided. The second chip 100W includes a substrate 100. The substrate 100 may be a semiconductor substrate, such as a silicon-containing substrate. The substrate 100 may include regions R1′ and R2′. The region R1′ is also called a memory array region, and the region R2′ is also called a staircase region. The region R1′ may include a first sub-region SR1′ and a second sub-region SR2′ (as shown in FIG. 4A). Referring to FIG. 3 and FIG. 4A, after the subsequent bonding process, the first sub-region SR1′ of the region (memory array region) R1′ of the second chip 100W will overlap with the region (page buffer region) R1 of the first chip 10W. The second sub-region SR2′ of the region (memory array region) R1′ of the second chip 100W will overlap with the region (peripheral circuit region) R2 of the first chip 10W. The region (staircase region) R2′ of the second chip 100W will overlap with the region (row and column decoder region) R3 of the first chip 10W.

Back to FIG. 1A, an insulating layer 101 and a stop layer 103 are formed on the substrate 100 in the regions R1′, R2′. The insulating layer 101 may include silicon oxide. The stop layer 103 is formed on the insulating layer 101. The stop layer 103 may include multiple conductive layers 94 and multiple insulating layer 92 stacked alternately and an insulating structure 105. The conductive layer 94 includes polysilicon, and the insulating layer 92 and the insulating structure 105 include silicon oxide.

Referring to FIG. 1A and FIG. 2A, a stack structure SK1 is formed on the stop layer 103 in the regions R1′, R2′. The stack structure SK1 includes multiple insulating layers 102 and multiple intermediate layers 104 stacked alternately. In some embodiments, the material of the insulating layers 102 includes silicon oxide, and the material of the intermediate layers 104 includes silicon nitride. The intermediate layers 104 may serve as sacrificial layers, which will be partially or completely removed in the subsequent processes.

Referring to FIG. 1A and FIG. 2A, next, the intermediate layers 104 and the insulating layers 102 of the stack structure SK1 in the region R2′ are patterned to form a staircase structure SC (shown in FIG. 1A). A dielectric layer 107 is formed above the substrate 100 to cover the staircase structure SC. The material of the dielectric layer 107 is, for example, silicon oxide.

Referring to FIG. 1A and FIG. 2A, a patterning process is performed to remove portions of the stack structure SK1, to form one or more openings 106 extending through the stack structure SK1. Then, a charge storage structure 108 is formed in the opening 106. The charge storage structure 108 is in contact with the insulating layers 102 and the intermediate layers 104. In an embodiment, the charge storage structure 108 is an oxide/nitride/oxide (ONO) composite layer.

Then, a vertical channel pillar VC is formed in a remaining space of the opening 106. The vertical channel pillar VC includes a channel layer 110, an insulating pillar 112 and a channel plug 114. The material of the channel layer 110 includes undoped polycrystalline silicon. The material of the insulating pillar 112 includes silicon oxide. The material of the channel plug 114 includes a doped semiconductor material, such as doped polycrystalline silicon. The charge storage structure 108 surrounds a vertical outer surface of the vertical channel pillar VC. After that, a dielectric layer 115 is formed over the substrate 100. The material of the dielectric layer 115 includes silicon oxide.

Referring to FIG. 1A and FIG. 2A, multiple support structures PIC and multiple through vias TV are formed. The support structures PIC and the through vias TV extend from the top surface of the dielectric layer 115 through the stack structure SK1 and the stop layer 103, so as to avoid the collapse of the stepped structure SC during the subsequent removal of the intermediate layers 104. The through vias TV will be connected to the interconnect lines in the subsequent manufacturing process, so the through vias TV can also be called signal contacts.

Referring to FIG. 1B and FIG. 2B, a dielectric layer 128 is formed on the dielectric layer 115. The dielectric layer 128 may include silicon oxide. Thereafter, a patterning process is performed to form one or more separation trenches 116. The separation trench 116 extends through the dielectric layer 128, the dielectric layer 115 and the stack structure SK1 to divide the stack structure SK1 into multiple blocks (not shown). The separation trench 116 may have vertical sidewalls or slightly inclined sidewalls (not shown).

Referring to FIG. 1B and FIG. 2B, a replacement process is performed, so as to replace portions of the intermediate layers 104 with the conductive layers 126. The conductive layers 126 may serve as gate layers or be called as word lines WL. The conductive layer 126 includes, for example, a barrier layer and a metal layer. In one embodiment, the material of the barrier layer includes titanium (Ti), titanium nitride (TiN), tantalum (Ta), tantalum nitride (TaN) or a combination thereof. The material of the metal layer includes tungsten (W). The portions of the intermediate layers 104 are replaced by the conductive layers 126, thus forming a stack structure SK2.

The stack structure SK2 includes a first part P1 and a second part P2. The first part P1 of the stack structure SK2 includes multiple insulating layers 102 and multiple intermediate layers 104 stacked alternately. The second part P2 of the stack structure SK2 includes multiple insulating layers 102 and multiple conductive layers 126 stacked alternately.

Referring to FIG. 1C and FIG. 2C, next, the conductive layer (not shown) formed in the separation trench 116 is removed, and a spacer 117 is formed on the sidewall of the separation trench 116. The spacer 117 includes a dielectric material different from the insulating layer 102, such as silicon nitride or a silicon oxide/silicon nitride/silicon oxide composite layer. Afterwards, the middle one of the conductive layers 94 and the insulating layers 92 thereabove and therebelow in the stop layer 103 are removed to form a horizontal trench 121. Then, a conductive layer 93 (such as a doped polysilicon layer) is filled in the horizontal trench 121 and a remaining space of the separation trench 116. The conductive layer 93 and the conductive layers 94 thereabove and therebelow in the horizontal trench 121 together form a common source column CSL. The conductive layer 93 and the spacer 117 in the separation trench 116 together form a slit structure SLT. The conductive layer 93 of the slit structure SLT is isolated from the conductive layers 126 by the spacer 117 to avoid undesired connection with each other. Thereafter, a stop layer 129 and a dielectric layer 130 are formed on the dielectric layer 128 to cover a top surface of the slit structure SLT. The stop layer 129 may include silicon nitride. The dielectric layer 130 may include silicon oxide.

Referring to FIG. 1C and FIG. 2C, then, multiple contacts COA are formed in the dielectric layer 130 and the dielectric layer 107 to electrically connect the conductive layer 126, the vertical channel pillar VC and the through vias TV, respectively.

Referring to FIG. 1C, FIG. 2C and FIG. 4A a second portion 30b of the interconnect structure 30 and bit lines BL are formed over the substrate 100. The second portion 30b of the interconnect structure 30 (shown in FIG. 1G and FIG. 2G) may include multiple dielectric layers 31b and interconnect layers 33b formed in the multiple dielectric layers 31b. The interconnect layers 33b include multiple plugs V2, multiple conductive lines CL2 or the like. The dielectric layer 31b separates adjacent conductive lines CL2 from each other. The conductive lines CL2 may be connected by the plugs V2, and the conductive lines CL2 may be connected to the contacts COA by the plugs V2. The second portion 30b of the interconnect structure 30 may be formed by a single damascene process, a dual damascene process, or any known method. The bit line BL is connected to the vertical channel pillar VC through the plug V2 and the contact COA.

Referring to FIG. 4A, for simplicity, only bit lines BL are shown in FIG. 4A. The bit lines BL are disposed in the region R1′ and extend from the first sub-region SR1′ to the second sub-region SR2′. The bit lines BL in the first sub-region SR1′ will be electrically connected to the page buffers PB disposed in the region R1 of the first chip 10W (shown in FIG. 3).

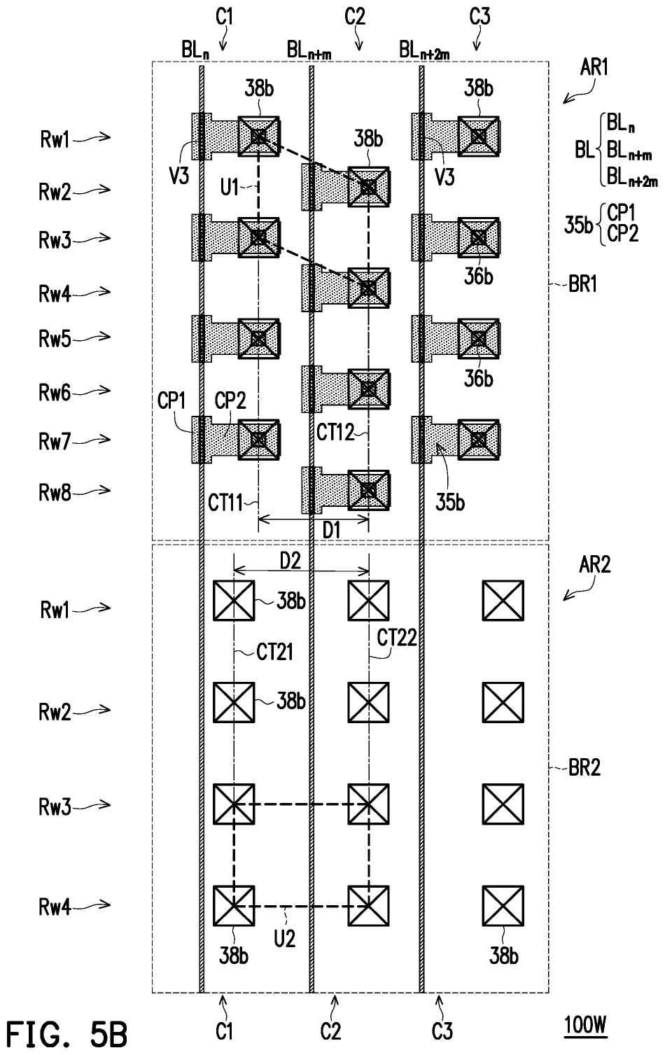

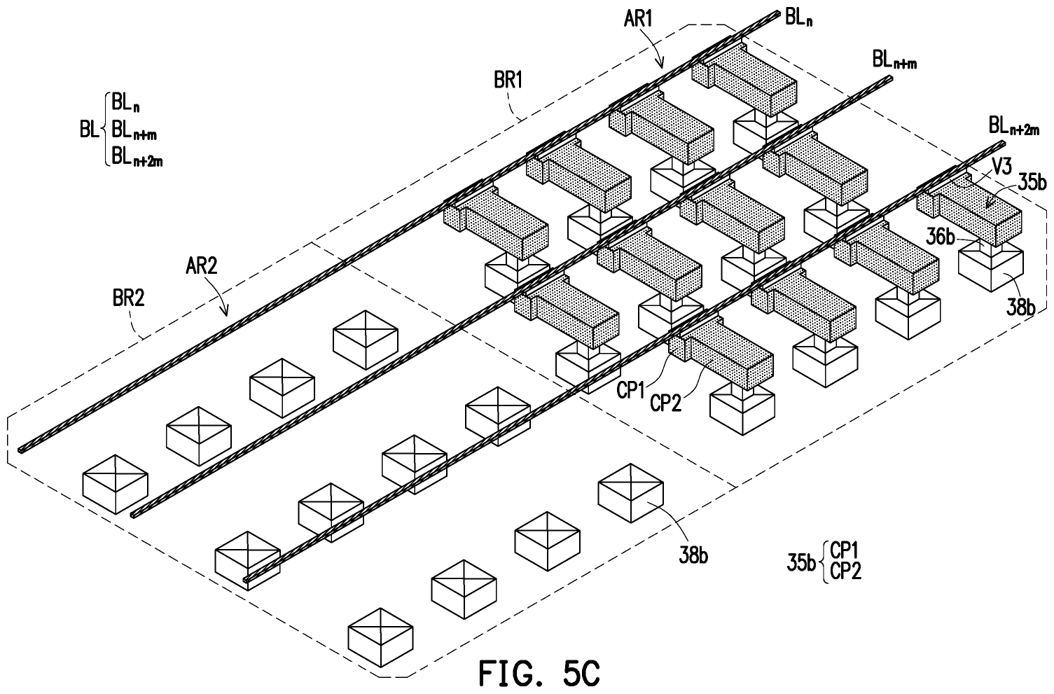

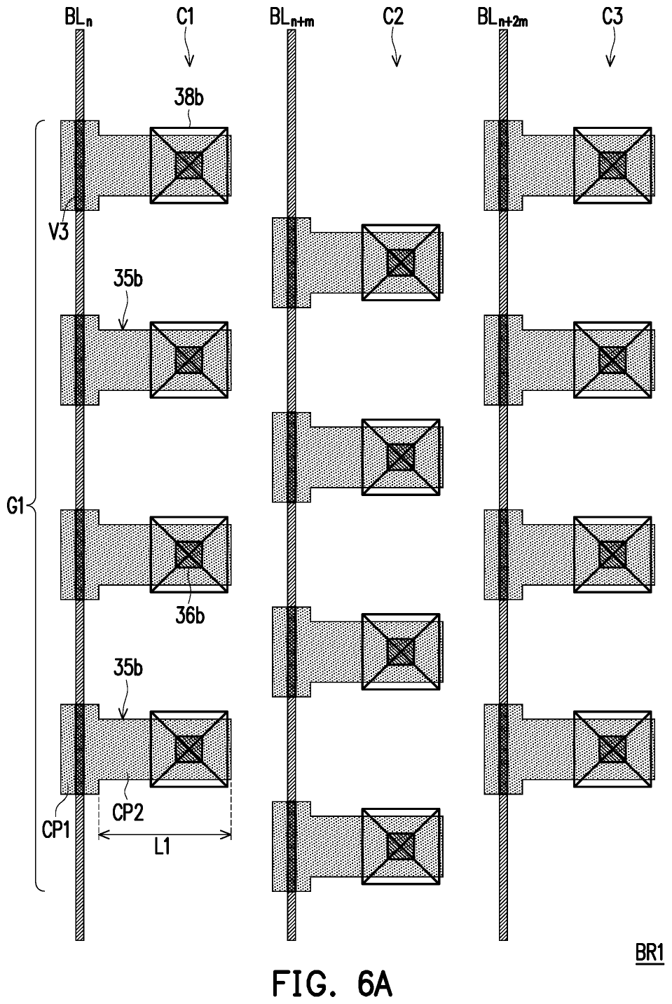

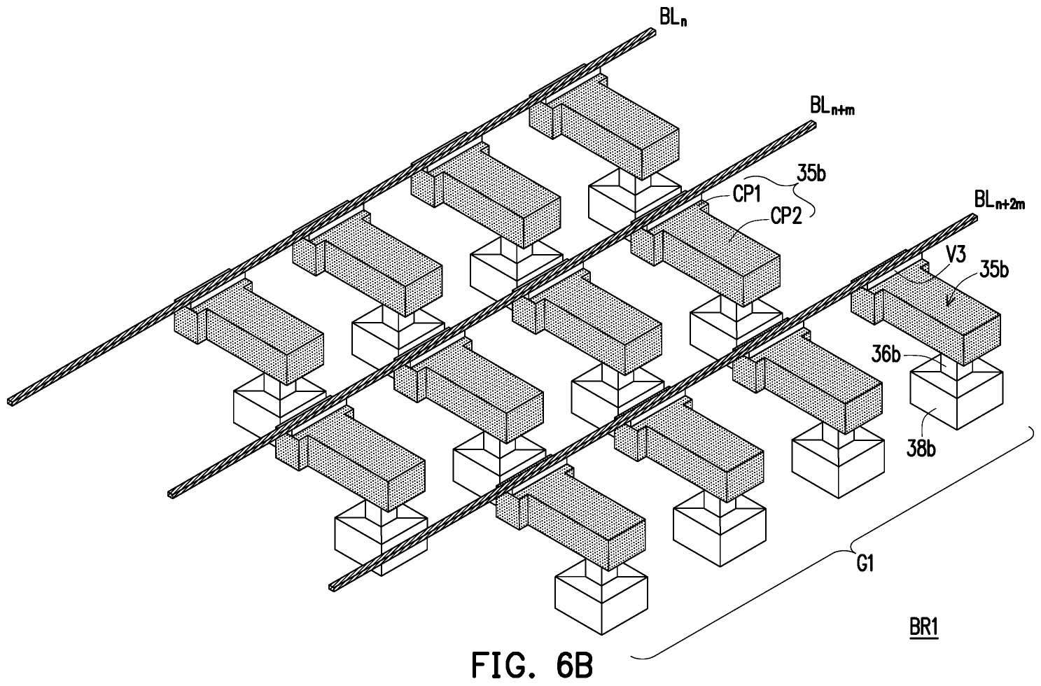

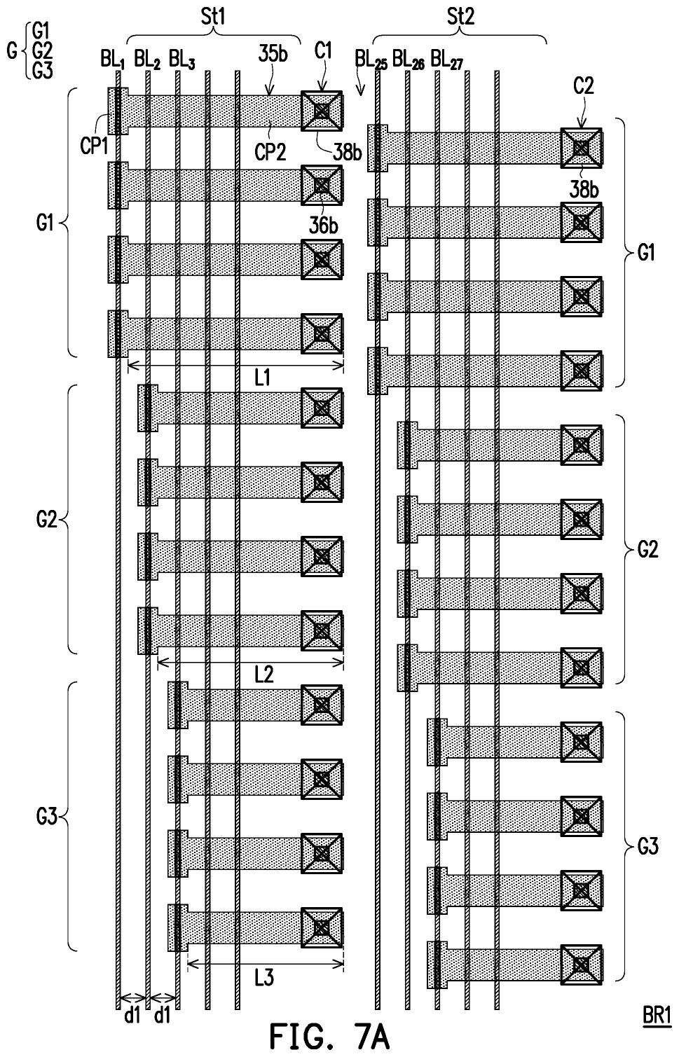

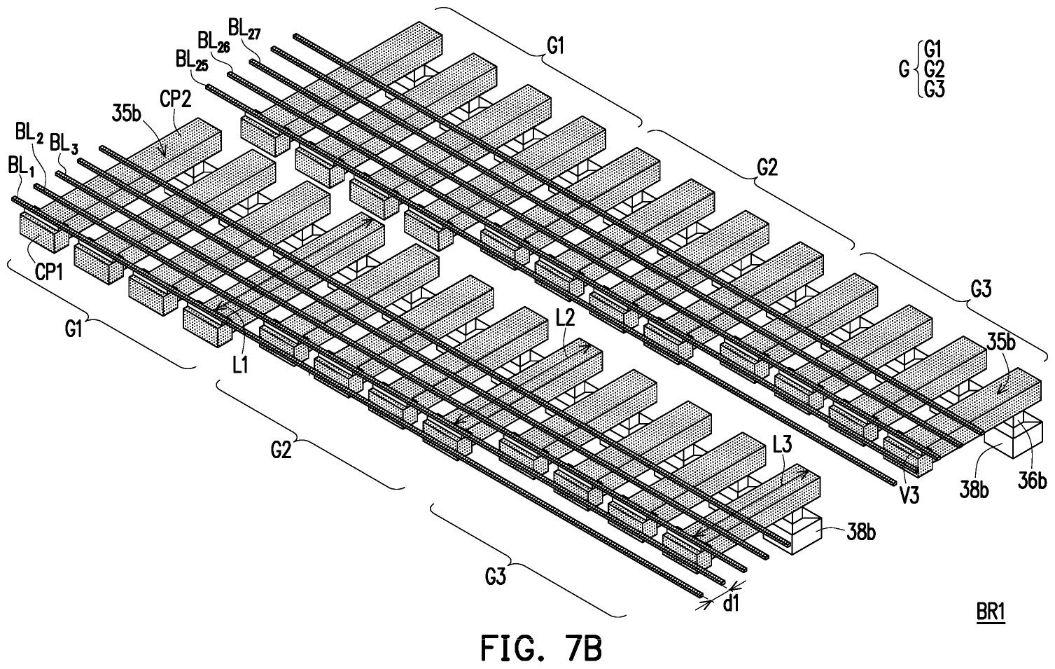

Referring to FIG. 1D and FIG. 2D, in the embodiments of the disclosure, a plurality of vias V3 and a plurality of connection features 35b are further formed on the bit lines BL. The via V3 connects the bit line BL and the connection feature 35b. The via V3 and the connection feature 35b may also be formed by a single damascene, a dual damascene process, or any known method. The connection relationship of the bit lines BL, the vias V3 and the connection features 35b may also be referred to FIG. 5C, FIG. 6B and FIG. 7B, which will be then described in detail.

Referring to FIG. 1E and FIG. 2E, a second portion 32b of the bonding structure 32 (shown in FIG. 1G) is formed on the second portion 30b of the interconnect structure 30. The second portion 32b of the bonding structure 32 includes a bonding dielectric layer 34b and a bonding plug 36b and a bonding pad 38b embedded in the bonding dielectric layer 34b. The bonding pad 38b is connected to the bit line BL through the bonding plug 36b and the connection feature 35b. The materials and forming methods of the bonding dielectric layer 34b, the bonding plug 36b, and the bonding pad 38b may be the same or similar to those of the bonding dielectric layer 34a, the bonding plug 36a, and the bonding pad 38a. The first portion 30a of the interconnect structure and the second portion 30b of the interconnect structure will form the interconnect structure 30 after performing the bonding process (shown in FIG. 1H and FIG. 2H). The bonding structure 32 is embedded in the interconnect structure 30.

Referring to FIG. 4B, in the embodiments of the disclosure, an arrangement of the bonding pads 38b in the first-sub region SR1′ of the region R1′ is different from an arrangement of the bonding pads 38b in the second-sub region SR2′ of the region R1′ and the second region R2′, so that the density of the bonding pads 38b in the first-sub region SR1′ of the region R1′ is greater than the density of the bonding pad 38b in the second-sub region SR2′ of the region R1′ and the second region R2′, which will be then described in detail.

Referring to FIG. 1F and FIG. 2F, the substrate 100 is turned over or flipped over, so that the second chip 100W and the first chip 10W are in a face-to-face configuration. The staircase structure SC on the flipped substrate 100 becomes a reverse staircase structure RSC. The contacts COA are under the reverse staircase structure RSC.

Referring to FIG. 1G and FIG. 2G, a bonding process is performed. In the embodiments of the disclosure, the second chip 100W and the first chip 10W are in a face-to-face configuration, and thus the bonding process is a face-to-face bonding process. The second portion 32b of the bonding structure 32 is bonded to the first portion 32a of the bonding structure 32, so as to form the bonding structure 32. In the bonding structure 32, the bonding dielectric layer 34b is correspondingly bonded to the bonding dielectric layer 34a, to form a dielectric layer 34. The bonding pad 38b is correspondingly bonded to the bonding pad 38a to form a bonding pad 38. The bonding dielectric layer 34b and the bonding dielectric layer 34a may be bonded by a dielectric-to-dielectric bonding. The bonding pad 38b and the bonding pad 38a may be bonded by a metal-to-metal bonding. The bonding structure 32 is disposed in the interconnect structure 30, and between the first portion 30a and the second portion 30b of the interconnect structure 30. The first portion 30a and the second portion 30b constitute an interconnect structure 30, and the bonding structure 32 is embedded in the interconnect structure 30. Next, the substrate 100 is removed to expose the insulating layer 101. The substrate 100 may be removed by grinding, polishing or etching.

Referring to FIG. 3 and FIG. 4B, after the bonding process is performed, the first sub-region SR1′ of the region R1′ of the second chip 100W will overlap with the region R1 of the first chip 10W. The second sub-region SR2′ of the region R1′ of the second chip 100W will overlap with the region R2 of the first chip 10W. The region R2′ of the second chip 100W will overlap with the region R3 of the first chip 10W.

Referring to FIG. 1H and FIG. 2H, the back-end process is performed. Contacts 46, conductive lines 48 and a dielectric layer 50 of an interconnect structure 40 are formed on the insulating layer 101. The conductive line 48 may be connected to the contact 46. The material of the conductive line 48 may include copper or tungsten, for example. The dielectric layer 50 may have a single-layer or multilayer structure. The material of the dielectric layer 50 may include silicon oxide, silicon oxynitride, silicon nitride or a combination thereof. The interconnect structure 40 may be electrically connected to the interconnect structure 30 by the through vias TV.

In other embodiments, a portion of the substrate 100 of the second chip 100W may be retained after thinning. After that, a semiconductor through via (or silicon through via) is formed in the substrate 100 to electrically connect the through via TV, and the back-end process is performed. The semiconductor through via (or silicon through via) may include an insulating liner (not shown) and a conductive layer (not shown).

In the embodiment, the word line WL may be electrically connected to the second portion 30b of the interconnect structure 30, the bonding structure 32, the first portion 30a and the device layer 20 through the contact COA.

The bit line BL may be electrically connected to the overlying channel column structure VC through the plug V2 of the second portion 30b of the interconnect structure 30 and the contact COA. The bit line BL may be electrically connected to the page buffer in the underlying device layer 20 through the bonding structure 32 and the first portion 30a in the interconnect structure 30.

Referring to FIG. 1H, the bonding pad 38a and the bonding pad 38b in the bonding structure 32 are bonded. Therefore, the position of the bonding pad 38a corresponds to the position of the bonding pad 38b. In the embodiments of the present disclosure, the bonding pads 38a and 38b have different configurations and densities depending on their locations.

For simplicity, the region (page buffer region) R1 of the first chip 10W and the first sub-region SR1′ of the region (memory array region) R1′ of the second chip 100W are collectively called a first region BR1, and the region (peripheral circuit region and row and column decoder region) R2, R3 of the first chip 10W and the second sub-region SR1′ of the region (memory array region) R1′ and the region (staircase region) R2′ of the second chip 100W are collectively called a second region BR2.

Referring to FIG. 3 and FIG. 4B, in the embodiments of the disclosure, the density of the bonding pads 38a and 38b in the first region BR1 is greater than the density of the bonding pads 38a and 38b in the second region BR2. In some embodiments, the bonding pad 38b in the first region BR1 is called a first bonding pad 38b, and the bonding pad 38b in the second region BR2 is called a second bonding pad 38b (as shown in FIG. 4B). The bonding pad 38a in the first region BR1 is called a third bonding pads 38a, and the bonding pad 38a in the second region BR2 is called a fourth bonding pad 38a (as shown in FIG. 3). The first bonding pad 38b and the third bonding pad 38a may also be called active bonding pads. The second bonding pad 38b and the fourth bonding pad 38a may also be called dummy bonding pads.

The bonding pads 38a and 38b in the first region BR1 may be arranged in a first array AR1. The bonding pads 38a and 38b in the second region BR2 may be arranged in a second array AR2. The arrangement of the first array AR1 is different from the arrangement of the second array AR2.

The arrangement of the bonding pad 38a in the first array AR1 is the same as the arrangement of the bonding pad 38b in the first array AR1. The arrangement of the bonding pad 38a in the second array AR2 is the same as the arrangement of the bonding pad 38b in the second array AR2. For the sake of simplicity, only bonding pad 38b is described below.

FIG. 5A to FIG. 5C are top views and a perspective view of a plurality of bonding pads and a plurality of bit lines in two adjacent regions (first region and second region). For the sake of clarity, in FIG. 5B and FIG. 5C, only one bit line BL (i.e., bit line BLₙ, BLₙ₊ₘ, BLₙ₊₂ₘ) is illustrated to represent a corresponding set St of bit lines, where n and m are integers.

Referring to FIG. 5A to FIG. 5C, multiple bonding pads 38b of the first array AR1 are disposed in the first region BR1. In FIG. 5A and FIG. 5B, the first array AR1 is only represented by multiple bonding pads 38b in 3 columns and 8 rows (C1˜C3, Rw1˜Rw8), but the disclosure is not limited thereto. The first array AR1 may include more columns and rows. In the first array AR1, the bonding pads 38b in two adjacent rows are arranged alternately, and the bonding pads 38b in two adjacent columns are arranged alternately. The first array AR1 is the closest-packed arrangement, for example. In addition, four centers of the four adjacent bonding pads 38b in two adjacent columns, such as four centers of the bonding pads 38b11 and 38b12 in the first column C1 and the bonding pads 38b21 and 38b22 in the second column C2, are connected to form a rhombus unit U1.

Referring to FIG. 5A, multiple bonding pads 38b of the second array AR2 are disposed in the second region BR2. In FIG. 5A, the second array AR2 is only represented by multiple bonding pads 38b in 3 columns and 4 rows (C1˜C3, Rw1˜Rw4), but the disclosure is not limited thereto. The second array AR2 may include more columns and rows. In the second array AR2, the bonding pads 38b in two adjacent rows are arranged oppositely, and the bonding pads 38b in two adjacent columns are arranged oppositely. In addition, four centers of the four adjacent bonding pads 38b in two adjacent columns, such as four centers of the bonding pads 38b15 and 38b16 in the second column C1 and the bonding pads 38b25 and 38b26 in the second column C2, are connected to form a rectangular unit or a square unit U2.

Referring to FIG. 5A, in the embodiments of the disclosure, multiple bit lines BL extend from the first region BR1 to the second region BR2. The multiple bit line BLs may be divided into multiple sets St of bit lines. In the first region BR1, one set St of bit line BL passes between the bonding pads 38b in two adjacent columns. Each set St of bit lines BL has m bit lines BL, where m is an integer, such as 24, 48, 96 or more. For the convenience of description, m is exemplified as 24 for illustration. For example, 24 bit lines BL of the second set St2 span between the bonding pads 38b in the first column C1 and the bonding pads 38b in the second column C2. Similarly, 24 bit lines BL of the third set St3 span between the bonding pads 38b in the second column C2 and the bonding pads 38b in the third column C3.

In the embodiments of the disclosure, m bit lines BL of each set St are connected to multiple bonding pads 38b in the same column. For example, 24 bit lines BL of the first set St1 are connected to the multiple bonding pads 38b in the first column C1. Similarly, 24 bit lines BL of the second set St2 are connected to the multiple bonding pads 38b in the second column C2. 24 bit lined BL of the third set St3 are connected to the multiple bonding pads 38b in the third column C1. 24 bit lines BL of the fourth set St4 are connected to the multiple bonding pads 38b in the fourth column (not shown).

Referring to FIG. 5B and FIG. 5C, in the embodiments of the disclosure, multiple bit lines BL are disposed above the multiple bonding pads 38b in the first region BR1 and the second region BR2. However, the multiple bit lines BL are only electrically connected to the multiple bonding pads 38b in the first region BR1, but are not electrically connected to the bonding pad 38b in the second region BR2. Furthermore, in the embodiments of the present disclosure, each bonding pad 38b in the first region BR1 may be electrically connected to one of the bit lines BL. In other words, each bonding pad 38b in the first region BR1 is a functional and active bonding pad, and no bonding pad 38b is dummy. Therefore, the disclosure may effectively utilize each bonding pad 38b and prevent the bonding pad 38b from being wasted.

FIG. 6A and FIG. 6B are a top view and a perspective view of a plurality of bonding pads and a plurality of bit lines of the same group in the same region.

Referring to FIGS. 5B and 5C and FIGS. 6A and 6B, in the embodiments of the disclosure, each bit line BL may be electrically connected to multiple (for example, more than three) bonding pads 38b in the first region BR1, and then to electrically connect the page buffer PB in the underlying device layer 20 (shown in FIG. 3). In FIGS. 5B to 6B, each bit line BL may be electrically connected to four bonding pads 38b. Since each bit line BL may be electrically connected to multiple bonding pads 38b, even if the bit line BL may not be connected to one of the multiple bonding pads 38b, the bit line BL may still be connected to others of the multiple bonding pads 38b normally. Therefore, the disclosure may improve the reliability of the memory device.

Referring to FIG. 5B, the first distance D1 between the two centerlines CT11 and CT12 of multiple bonding pads 38b in two adjacent columns (for example, C1 and C2) in the first array AR1 is less than the second distance D2 between the two centerlines CT21 and CT22 of multiple bonding pads 38b in two adjacent columns (For example, C1 and C2) in the second array AR2. Therefore, the embodiments of the present disclosure may enable the bit line BL to be connected to more bonding pads 38b without increasing the occupied chip area.

Referring to FIGS. 5B and 5C and FIGS. 6A and 6B, in the embodiments of the disclosure, the bit line BL in the first region BR1 may electrically connect multiple bonding pads 38b through multiple vias V3, multiple connection features 35b and multiple bonding plugs 36b. The multiple connection features 35b are disposed between the multiple bit lines BL and the multiple bonding pads 38b. Each bit line BL is connected to the multiple connection features 35b through the multiple vias V3. The multiple connection features 35b are connected to the multiple bonding pads 38b through the multiple bonding plugs 36b.

Each connection feature 35b may include a first connection portion CP1 and a second connection portion CP2 connected to each other. The first connection portion CP1 is connected to the bit line BL, and the second connection portion CP2 is connected to the bonding plug 36b. The first connection portion CP1 and the second connection portion CP2 extend along different directions. Multiple first connection portions CP1 connected to the same bit line BL are arranged into one column and have approximately the same length and width. Multiple second connection portions CP2 connected to the same bit line BL have approximately same length L1 and width.

Referring to FIGS. 5B and 5C and FIGS. 6A and 6B, in the embodiments of the disclosure, the bit line BL in the second region BR2 is not connected to the bonding pad 38b. Therefore, multiple vias V3, multiple connection features 35b and multiple bonding plugs 36b are not disposed in the second region BR2.

FIG. 7A and FIG. 7B are a top view and a perspective view of a plurality of bonding pads and a plurality of bit lines of different groups in the same region.

Referring to FIG. 7A and FIG. 7B, in some embodiments, the multiple bonding pads 38b in the same column may be divided into multiple groups G of bonding pads 38b, such as a first group G1, a second group G2, and a third group G3. Each group G has multiple bonding pads 38b, for example, three or more bonding pads 38b. In FIG. 7A and FIG. 7B, each group G in the first column C1 or the second column C has 4 bonding pads 38b. However, the disclosure is not limited thereto.

Referring to FIG. 7A and FIG. 7B, in the embodiment, in the first region BR1, multiple connection features 35b in two adjacent columns are arranged alternately. Multiple first connection portions CP1 of the multiple connection features 35b connecting the multiple bonding pads 38b of the same group G in the same column are arranged into one column. For example, multiple first connection portions CP1 connecting multiple bonding pads 38b of the first group G1 in the first column C1 are arranged into one column. Multiple first connection portions CP1 connecting multiple bonding pads 38b of the second group G2 in the first column C1 are arranged into another column. In other words, the multiple first connection portions CP1 connecting different groups of bonding pads 38b in the same column are offset from each other by a distance d1. For example, the multiple first connection portions CP1 connecting the bonding pads 38b of the first group G1 in the first column C1 and the multiple first connection portions CP1 connecting the bonding pads 38b of the second group G2 in the first column C1 are not arranged into one column. Instead, they are offset by a non-zero distance d1.

Referring to FIG. 7A and FIG. 7B, the multiple connection features 35b connecting the multiple bonding pads 38b of the same group in the same column have the same length. The multiple connection features 35b connecting the multiple bonding pads 38b of different groups in the same column have different lengths. In the embodiment, the multiple first connection portions CP1 of the multiple connection features 35b in the first region BR1 have the same length and width, and the multiple connection features 35b are connected to the bonding plugs 36b by changing the lengths of the multiple second connection portions CP2.

The multiple second connection portions CP2 connecting multiple bonding pads 38b of the same group G in the same column have the same length. For example, the multiple second connection portions CP2 connecting the bonding pads 38b of the first group G1 in the first column C1 have the same first length L1. The second connection portions CP2 connecting the bonding pad 38b of the second group G2 in the first column C1 have the same second length L2. The second connection portions CP2 connecting the bonding pads 38b of the third group G3 in the first column C1 have the same third length L3.

The multiple second connection portions CP2 connecting multiple bonding pads 38b of different groups G in the same column have different lengths. For example, the multiple second connection portions CP2 connecting the bonding pads 38b of the first group G1 in the first column C1 have the same first length L1. The first length L1 is larger than a second length L2 of the second connection portions CP2 connecting the bonding pad 38b of the second group G2 in the first column C1, and the first length L1 is much larger than a third length L3 of the second connection portions CP2 connecting the bonding pads 38b of the third group G3 in the first column C1.

In the above embodiments, the bonding structure 32 is disposed on the front side of the second chip 100W, and the second chip 100W is bonded to the first chip 10W in a face-to-face manner. However, invention is not limited thereto. In other embodiments, the bonding structure of the first chip 10W may also be arranged on the backside of the substrate 10, and the bonding structure of the second chip 100W may also be arranged on the backside of the substrate 100. Therefore, the second chip may be bonded to the first chip in various ways. For example, the second chip may be bonded to the first chip through a face-to-back bonding or a back-to-face bonding.

In addition, the above embodiments illustrate a 3D NAND flash memory. However, the disclosure is not limited thereto. The disclosure may also be applied to other memories such as 3D NOR flash memories or dynamic random access memories.

To sum up, in the memory device of the embodiments of the present disclosure, the density of the bonding pads in the memory array region overlapping with the page buffer region is increased. Thus, the number of the contacts connected to the bit line may be increased, and the electrical connection between the bit line and the contact may be ensured. Accordingly, the reliability of the memory device may be improved.

What is claimed is:

1. A memory device, comprising:
a substrate, comprising a first region and a second region adjacent to each other;
a bonding structure, disposed over the substrate, comprising:
a bonding dielectric layer, disposed over the substrate in the first region and the second region;
a plurality of first bonding pads, embedded in the bonding dielectric layer over the substrate in the first region; and
a plurality of second bonding pads, embedded in the bonding dielectric layer over the substrate in the second region; and
a plurality of bit lines, disposed over the bonding structure, the bit lines extending from the first region to the second region, wherein each of the first bonding pads is electrically connected to one of the bit lines, and
a density of the first bonding pads in the first region is greater than a density of the second bonding pads in the second region.

2. The memory device according to claim 1, wherein the first region comprises a first sub-region of a memory array region overlapping with a page buffer region, and the second region comprises a second sub-region of the memory array region overlapping with a peripheral circuit region.

3. The memory device according to claim 2, further comprising:
a plurality of third bonding pads, disposed in the bonding dielectric layer in the pager buffer region; and
a plurality of fourth bonding pads, disposed in the bonding dielectric layer in the decoder region and the peripheral circuit region,
wherein the third bonding pads are bonded to the corresponding first bonding pads, and the fourth bonding pads are bonded to the corresponding second bonding pads.

4. The memory device according to claim 1, wherein the first bonding pads are arranged in a first array, the second bonding pads are arranged in a second array, and an arrangement of the first array is different from an arrangement of the second array.

5. The memory device according to claim 4, wherein in the first array, the first bonding pads in two adjacent rows or two adjacent columns are arranged alternately.

6. The memory device according to claim 4, wherein in the first array, centers of two adjacent first bonding pads in a first column and centers of two adjacent first bonding pads in a second column adjacent to the first column are connected to form a rhombus-shaped unit.

7. The memory device according to claim 4, wherein a first distance between first centerlines of the first bonding pads in two adjacent columns of the first array is less than a second distance between second centerlines of the second bonding pads in two adjacent columns of the second array.

8. The memory device according to claim 4, wherein in the second array, the second bonding pads in two adjacent rows are arranged oppositely to each other, and the second bonding pads in two adjacent columns are arranged oppositely to each other.

9. The memory device according to claim 8, wherein in the second array, centers of two adjacent second bonding pads in a first column and centers of two adjacent second bonding pads in a second column adjacent to the first column are connected to form a rectangular unit or a square unit.

10. The memory device according to claim 4, wherein the first bonding pads in each column of the first array comprise a plurality of groups of first bonding pads, and each of the groups of first bonding pads in a same column of the first array is electrically connected to one of the bit lines.

11. The memory device according to claim 10, wherein each of the groups of first bonding pads in each column is electrically connected to the corresponding bit lines.

12. The memory device according to claim 11, wherein one of the groups of first bonding pads comprises at least three first bonding pads.

13. The memory device according to claim 10, further comprising a plurality of connection features, wherein each of the connection features is electrically connected to one of the first bonding pads and one of the bit lines.

14. The memory device according to claim 13, wherein the connection features comprise:
a plurality of first connection portions electrically connected to the bit lines; and
a plurality of second connection portions electrically connected to the first bonding pads.

15. The memory device according to claim 14, further comprising:
a plurality of vias, connecting the first connection portions and the bit lines; and
a plurality of bonding plugs, connecting the second connection portions and the first bonding pads.

16. The memory device according to claim 14, wherein the second connection portions connecting one of the groups of first bonding pads in a same column have a same length.

17. The memory device according to claim 14, wherein the second connection portions connecting different ones of the groups of first bonding pads in a same column have different lengths.

18. The memory device according to claim 14, wherein the first connection portions connecting one of the groups of first bonding pads in a same column are arranged into one column.

19. The memory device according to claim 14, wherein the first connection portions connecting different ones of the groups of first bonding pads in a same column are offset from each other.

20. The memory device according to claim 10, wherein in the second region, the bit lines extending over the second bonding pads are not electrically connected to the second bonding pads.
